(19) United States
(12) Patent Application Publication
(10) Pub. No.: US 2026/0229304 A1
(43) Pub. Date: Aug. 6, 2026

(54) INPUT/OUTPUT CIRCUIT FOR MEMORY AND OPERATING METHOD THEREOF

(71) Applicant: TAIWAN SEMICONDUCTOR MANUFACTURING COMPANY LTD., HSINCHU (TW)

(72) Inventors: HUA-HSIN YU, HSINCHU CITY (TW); CHIEN-YU HUANG, TAOYUAN CITY (TW); CHENG HUNG LEE, HSINCHU (TW); HUNG-JEN LIAO, HSIN-CHU CITY (TW)

(21) Appl. No.: 19/044,648

(22) Filed: Feb. 4, 2025

(51) Int. Cl. G11C 29/12; G11C 29/14

(52) U.S. Cl. CPC G11C 29/1201; G11C 29/12015; G11C 29/14

(57) ABSTRACT

An input/output circuit for a memory array is provided. First latch circuit is coupled between first data line and second data line. First transistor is coupled between the first bit line and the first data line. Second transistor is coupled between the second bit line and the second data line. Bypass circuit is configured to directly receive a data signal and indirectly receive a write enable signal to generate a first signal. The first latch circuit includes an inverter having an input for receiving the first signal, a first switch coupled between the first data line and the input of the inverter; and a second switch coupled between the second data line and an output of the inverter. The inverter and the bypass circuit are configured to be powered by a first power supply voltage that is different from a second power supply voltage of the memory array.

### BACKGROUND

In a memory circuit designed for testability (DFT), several components are incorporated, including a D-flip-flop circuit, a write-in latch circuit, a read-out sense amplifier, and an output-Q-latch circuit. However, during the DFT test mode, the sense amplifier and the output-Q-latch circuit remain idle, whereas in the write mode, the sense amplifier alone is idle. The DFT memory circuit can further include a write-in and shadow latch circuit, a 3-to-1 multiplexer (MUX), a passive matrix (PM) isolation (ISO) clamping circuit, and a power-saving logic circuit. The presence of these additional features incurs a significant area penalty in memory design, impacting the overall size of the circuit.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 illustrates a block diagram of a memory device, in accordance with some embodiments of the present disclosure.

FIG. 2 illustrates a schematic diagram of the input/output (I/O) circuit of FIG. 1, in accordance with some embodiments of the present disclosure.

FIGS. 3A-3G illustrate the relationships between the signals of the I/O circuit and each mode of the memory, in accordance with some embodiments of the present disclosure.

FIG. 4 illustrates a detailed schematic diagram of the I/O circuit of FIGS. 1 and 2 in a read mode, in accordance with some embodiments of the present disclosure.

FIG. 5 illustrates a detailed schematic diagram of the I/O circuit of FIGS. 1 and 2 in a write mode, in accordance with some embodiments of the present disclosure.

FIG. 6 illustrates waveforms of signals in the I/O circuit in FIGS. 4 and 5, in accordance with some embodiments of the present disclosure.

FIG. 7 illustrates a detailed schematic diagram of the I/O circuit of FIGS. 1 and 2 in a DFT test mode, in accordance with some embodiments of the present disclosure.

FIG. 8 illustrates waveforms of signals in the I/O circuit in FIG. 7, in accordance with some embodiments of the present disclosure.

FIGS. 9A and 9B illustrates waveforms of signals propagating from VDD domain to VDDM domain in the I/O circuit in FIG. 7, in accordance with some embodiments of the present disclosure.

FIG. 10 illustrates a detailed schematic diagram of the I/O circuit, in accordance with some embodiments of the present disclosure.

FIG. 11 is a flowchart of a method for operating the I/O circuit of FIGS. 1 and 2, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath”, “below”, “above”, “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

A design for testability (DFT) function can be required in a memory design which may include at least one of: a latch circuit, a flip-flop circuit, or a combinational logic circuit. In some approaches, test patterns (e.g., binary vectors) are applied as SI inputs to a DFT circuit. The present disclosure provides a memory device with a DFT function by replacing a DFT D-flip-flop circuit and a write-in latch circuit with an existing read-out sense amplifier and a data output latch circuit (e.g., referred to a Q latch). The present disclosure can eliminate the need for write and shadow latches related circuits in every input/output (I/O) circuit, resulting in improved area usage and reduced area overhead. This is achieved by eliminating the need for additional logic circuits such as a write-in latch, a shadow latch, a 3-to-1 multiplexer (MUX), a passive matrix (PM) clamping circuit, and a power-saving logic circuit.

In some embodiments, a sense amplifier may cooperate with data output latch circuit (e.g., referred to a Q latch) for generating the result of the test in the test mode, instead of being idle according to some approaches. Accordingly, additional shadow latch circuit applied for shifting test pattern in the test mode is eliminated from the DFT circuit. Moreover, as described previously, a write-in latch for performing a write operation usually would not operate simultaneously as the write-in latch could be idle during a read operation and the sense amplifier is being pre-charged during a write operation. The disclosure replaces a write-in latch by modifying an existing sense amplifier and a level shifter so as to reduce the area taken up by the original write-in latch. By doing so, the power consumption and leakage current can be reduced, as the replacement does not require any additional power consumption or introduce new leakage current.

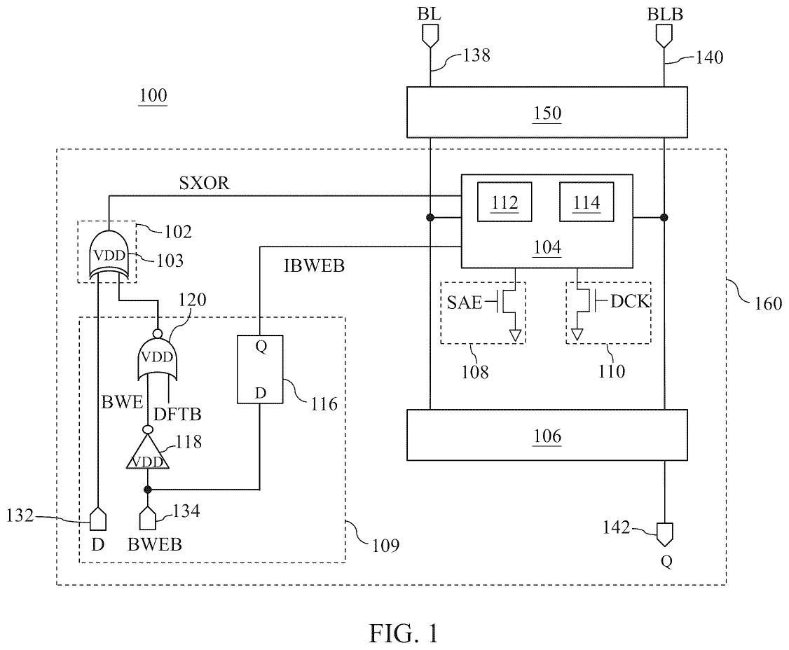

FIG. 1 illustrates a block diagram of a memory device 100, in accordance with some embodiments of the present disclosure. The memory device 100 include an input/output (I/O) circuit 160 and a memory array 150. The memory array 150 includes multiples memory cells (not shown) arranged in rows and columns of the memory array 150, and the memory cells are powered by a power supply voltage VDDM. The I/O circuit 160 includes an input circuit 109, a bypass circuit 102, a first latch circuit 104, a second latch circuit 106, a first transistor 108, and a second transistor 110. The input circuit 109 may be operatively coupled to the bypass circuit 102. The input circuit 109 includes a D latch circuit 116, an inverter 118, and a NOR gate 120.

The bypass circuit 102 includes an exclusive OR (XOR) gate 103, and the XOR gate 103 has two inputs coupled to the input circuit 109, and one output coupled to the first latch circuit 104. The bypass circuit 102 is configured to directly receive a data signal D from an input terminal (or input port) 132 and indirectly receive a write enable signal BWEB from an input terminal 134. In some embodiments, the bypass circuit 102 may have one of its inputs configured to receive the write enable signal BWEB at least through the inverter 118 and the NOR gate 120. In some embodiments, the write enable signal BWEB stands for Bit-Write-Enabled-Bar function which performs logical inversion of enabling a bit write signal. The NOR gate 120 may have one of its inputs configured to receive a test enable signal DFTB. When the test enable signal DFTB is at a first logic level (e.g., “1”), the memory device 100 is configured at a non-test mode (i.e., a normal mode), and when the test enable signal DFTB is at a second logic level (e.g., “0” or a grounding voltage), the memory device 100 is configured at a test mode. The NOR gate 120 may have the other one of its inputs configured to receive a write enable signal BWE. The D latch circuit 116 may be configured to receive the write enable signal BWEB and provide the control signal IBWEB to the write control circuit 251. In some embodiments, the D latch circuit 116 is a low-pass latch circuit which allows data to pass through when a clock phase is low (e.g., low logic level, “0”). The exclusive OR (XOR) gate 103 is configured to generate a bypass data signal SXOR according to the data signal D and the write enable signal BWEB. The output of the bypass circuit 102 is coupled to the first latch circuit 104 to transmit the bypass data signal SXOR to a first switch 112 and a second switch 114.

The first latch circuit 104 can be operatively coupled between a first bit line 138 (e.g., bit line (BL)) and a second bit line 140 (e.g., bit line bar (BLB)). The first latch circuit 104 may include a first switch 112 and a second switch 114 operatively coupled between the output of the bypass circuit 102 and the second latch circuit 106. The first switch 112 is operatively coupled between the data line DL and the output (e.g., the bypass data signal SXOR) of the bypass circuit 102. The second switch 114 is operatively coupled between the data line DLB and the output (e.g., the bypass data signal SXOR) of the bypass circuit 102. In some embodiments, the first latch circuit 104 can be a sense amplifier. The first latch circuit 104 can be a master latch of the data signal D. The first latch circuit 104 may replace a write-in latch for the data signal D. The first latch circuit 104 can be configured to sensing signals from respective the data lines DL and DLB that represent data bits (1 or 0) stored in respective memory cells, and to amplify a small voltage swing to recognizable logic levels so the data can be interpreted properly by logic circuitry coupled to the memory device 100. In some embodiments, the first latch circuit 104 can be coupled to a memory array 150 through the first bit line 138 and the second bit line 140. In some embodiments, the memory cells arranged in the same column are coupled to the same first bit line 138 and the same second bit line 140.

The second latch circuit 106 can be operatively coupled to the first latch circuit 104. The second latch circuit 106 can be configured to generate an output signal Q to an output terminal 142 based on a voltage level presented on the data line DLB. In some embodiments, the second latch circuit 106 is implemented as a high-pass latch circuit that allows data to pass through when a clock phase is high (e.g., high logic level, “1”). The first latch circuit 104 and the second latch circuit 106 collectively operate as a data flip-flop (e.g., D-flip-flop) in at least one of a plurality of operation modes (e.g., a normal mode or a test mode) where a clock signal (e.g., a DCK signal) is disabled and a sense enable signal (e.g., a Enable signal SAE) toggles as a clock source for the data flip-flop.

The first transistor 108 can be coupled to the first latch circuit 104 and gated by a sense enable signal SAE. The second transistor 110 can be coupled to the first latch circuit 104 and gated by a clock signal DCK. The first transistor 108 and the second transistor 110 can be alternately activated in each of a plurality of operation modes (e.g., a normal mode or a test mode) of the memory device 100 (e.g., the I/O circuit 160).

In some embodiments, the memory device 100 has different modes of operation, including a NORMAL mode (e.g., a read mode or a write mode) and a DFT test mode (e.g., a SHIFT mode, and a CAPTURE mode), while the SHIFT mode includes two sub-modes referred to as SCAN and DEBUG.

In the NORMAL mode (e.g., a read mode or a write mode), the memory device 100 does not perform any testing; instead, the memory device 100 performs its regular functionality that it is designed to perform, such as enabling reading and writing of data from/to the memory array 150. In some embodiments, a NORMAL path proceeds through the input portion, the memory core logic portion and then the output portion. Specifically, for example, the NORMAL path proceeds through the bypass circuit 102, the first latch circuit 104, and the second latch circuit 106 in the write mode or the read mode. For example, in a non-DFT test mode (e.g., a read mode or a write mode), the test enable signal DFTB may be set at “1”, which allows the bypass circuit 102 to pass the directly received data signal D through the XOR gate 103 and to output the bypass data signal SXOR (i.e., the data signal D) to the first latch circuit 104. When the memory device 100 is at a read mode, the second transistor 110, the first switch 112, and the second switch 114 are deactivated (e.g., disabled), and the first transistor 108 is activated (e.g., enabled). When the memory device 100 is at a write mode, the first transistor 108 is deactivated, and the second transistor 110, the first switch 112, and the second switch 114 are activated.

In the DFT test mode, test-related features are invoked, and various testing functionality is performed on the memory device 100 by applying certain input data (e.g., a data signal D and a write enabled signal BWEB) to the memory device 100. For example, in the DFT test mode, the DFTB signal may be set at “0”, which allows the bypass circuit 102 to generate the bypass data signal SXOR according to the directly received data signal D and the indirectly received write enable signal BWEB. The memory device 100 may compare an output data (e.g., the output signal Q from the second latch circuit 106) with “designed” output data that the memory device 100 is designed to produce. If the observed output matches the “designed” output then the memory device 100 passes the test; if the observed output does not match the “designed” output, the memory device 100 fails the test. When the memory device 100 is at a test mode, the first transistor 108, the first switch 112, and the second switch 114 are activated, and the second transistor 110 is deactivated.

In SHIFT mode and CAPTURE mode, which can be considered as test modes, tests are performed on different parts of the memory device 100. In the CAPTURE mode of the DFT test mode, the data signal D is outputted to a first input of the bypass circuit 102 directly; and the write enable signal BWEB is outputted to a second input of the bypass circuit 102 through the inverter 118 and the NOR gate 120. The data of the data signal D can be further latched in the first latch circuit 104 and the second latch circuit 106, and read out as the output signal Q. In some embodiments, the write enable signal BWEB can be programmed for performing testing. In the SHIFT mode of the DFT test mode, the data signal D is outputted to a first input of the bypass circuit 102 directly; and the write enable signal BWEB is outputted to a second input of the bypass circuit 102 through the inverter 118 and the NOR gate 120. The first latch circuit 104 may provide a data signal corresponding to the data signal D to the second latch circuit 106 for temporary storage of test data. In some embodiments, a CAPTURE path and a SHIFT path both pass through the input portion and proceed through the memory core logic portion, and then to the output portion. Specifically, for example, both of the CAPTURE path and the SHIFT path proceed through the first latch circuit 104 and the second latch circuit 106 in the memory core logic portion. The details of configurations and operations will be discussed in the following paragraphs.

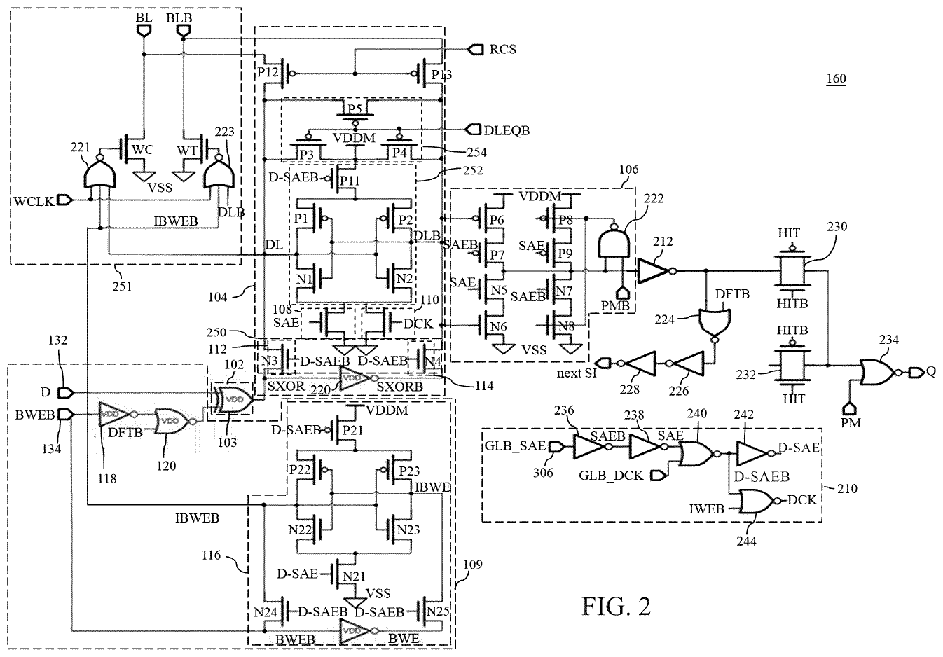

In some embodiments, a system includes multiple memory devices 100 that sequentially coupled with each other, in which a first memory device 100 receives a data signal (referred to as a data signal inputted as the data signal D of FIG. l) from external test device and a read out data (e.g., a signal generated by an inverter 212 in FIG. 2) from the first memory device 100 is transmitted as a data signal (inputted as the data signal D of FIG. 1) to a following memory device 100, and so on.

The configurations of FIG. 1 are given for illustrative purposes. Various implements are within the contemplated scope of the present disclosure. For example, in some embodiments, the D latch circuit 116 is not included in the bypass circuit 102.

FIG. 2 illustrates a schematic diagram of the I/O circuit 160 of FIG. 1, in accordance with some embodiments of the present disclosure. The I/O circuit 160 includes an input circuit 109, a bypass circuit 102, a first latch circuit 104, a second latch circuit 106, a first transistor 108, and a second transistor 110. The input circuit 109 is configured to transmit signals corresponding to the data signal D from the input terminal 132 and the write enable signal BWEB from the input terminal 134 to the bypass circuit 102. The data signal D is directly transmitted to the bypass circuit 102. The write enable signal BWEB is transmitted to the bypass circuit 102 at least through the inverter 118 and the NOR gate 120. The bypass circuit 102 may include the exclusive OR (XOR) gate 103 configured to generate the bypass data signal SXOR according to the data signal D and the write enable signal BWEB.

The additional logic circuit, such as the inclusion of the inverter 118 and the NOR gate 120, within the input circuit 109 can be utilized to eliminate the need for a data-in latch and a shadow latch related circuits. The NOR gate 120 may have one of its inputs configured to receive a test enable signal DFTB. Due to the additional logic circuit, two test modes (e.g., non-DFT test mode and DFT test mode) can be defined. In the non-DFT test mode, the first latch circuit 104 can function as a write-in latch. In the DFT test mode, the first latch circuit 104 and the second latch circuit 106 collectively operate as a data flip-flop (e.g., D flip-flop).

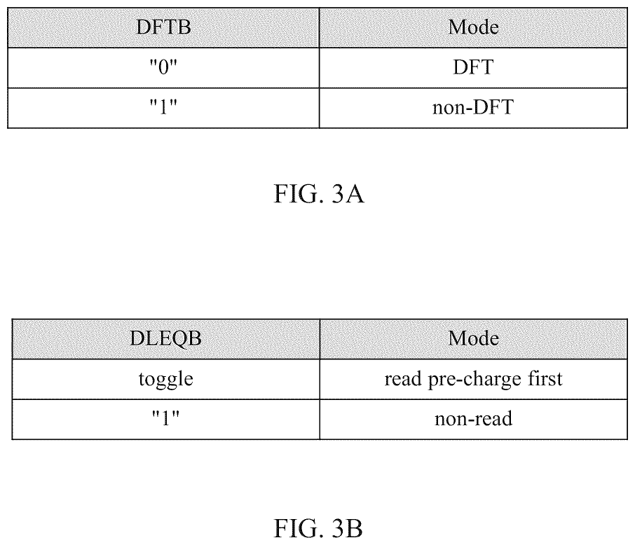

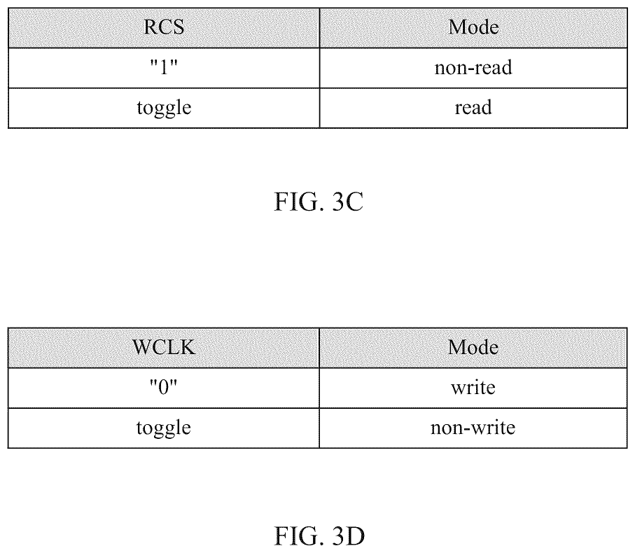

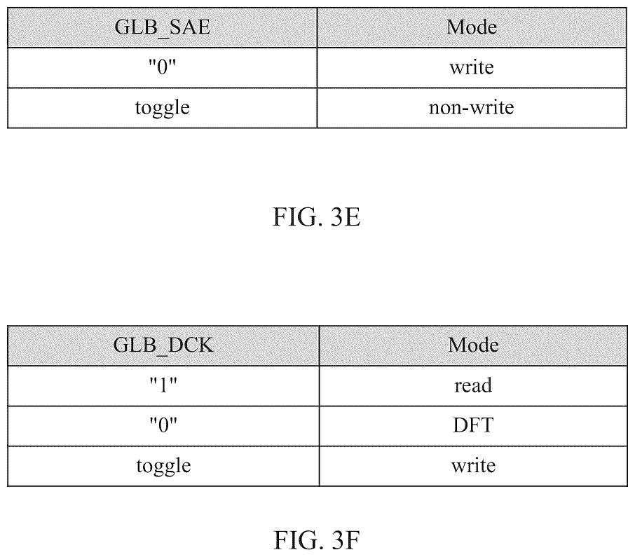

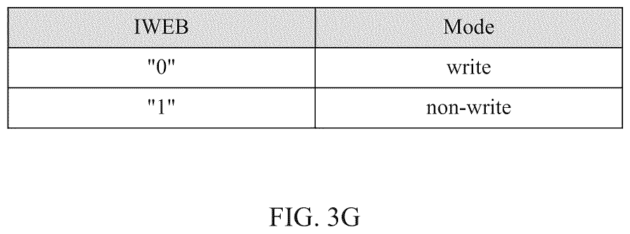

In the non-DFT test mode, the test enable signal DFTB can be at a high logic level “1”, which can make the NOR gate 120 output a low logic level “0”. The relationship between the test enable signal DFTB and each mode is shown in FIG. 3A. The XOR gate 103 may receive the data signal D and the output “0” of the NOR gate 120. In such case, the XOR gate 103 may generate the bypass data signal SXOR (the data signal D), and may transmit the bypass data signal SXOR (i.e., the data signal D) to the first latch circuit 104. The inverter 220 of the first latch circuit 104 may generate an inverted bypass data signal SXORB according to the bypass data signal SXOR (i.e., the data signal D). The first latch circuit 104 may utilize the data signal D and the inverted bypass data signal SXORB as inputs to operate as a write-in latch. In the non-DFT test mode, the first latch circuit 104 can function as a write-in latch. In some embodiments, the first latch circuit 104 can be a sense amplifier.

In the DFT test mode, the test enable signal DFTB can be at a low logic level “0”, which can make the NOR gate 120 output the write enable signal BWEB. The XOR gate 103 may receive the data signal D and the write enable signal BWEB. In such case, the XOR gate 103 may generate the bypass data signal SXOR according to the data signal D and the write enable signal BWEB. The XOR gate 103 may transmit the bypass data signal SXOR to the first latch circuit 104. The inverter 220 of the first latch circuit 104 may generate the inverted bypass data signal SXORB according to the bypass data signal SXOR. The first latch circuit 104 may utilize the bypass data signal SXOR and the inverted bypass data signal SXORB as inputs to operate as a DFT D-flip-flop. In the DFT test mode, the first latch circuit 104 and the second latch circuit 106 collectively operate as a data flip-flop (e.g., D flip-flop) where a clock signal DCK is disabled and a sense enable signal SAE toggles as a clock source for the data flip-flop.

The D input terminal of the D latch circuit 116 is configured to receive the write enable signal BWEB. In some embodiments, the D latch circuit 116 is a low-pass latch circuit which allows data to pass through when a clock (e.g., the write enable signal BWEB) phase is low (e.g., a low logic level “0”). A low-pass latch circuit can be triggered by a momentary low signal on the input, which allows low-frequency or slowly changing signals to pass through while blocking high-frequency signals. In some embodiments, the D latch circuit 116 can be an input latch for the write enable signal BWEB, which changes a state of a latch according to the input write enable signal BWEB. The D latch circuit 116 can be controlled by the write enable signal BWEB.

In the embodiment of FIG. 2, the D latch circuit 116 includes the transistors P21-P23, the transistors N21-N25 and an inverter 122. The transistors P21-P23 are P-type transistors, and the transistors N21-N25 are N-type transistors. The inverter 122 is configured to invert the write enable signal BWEB to generate the signal BWE. It should be noted that the inverters 118 and 122 and the NOR gate 120 of the input circuit 109, and the XOR gate 103 of the bypass circuit 102 are powered by the power supply voltage VDD. The power supply voltage VDD is different from the power supply voltage VDDM of the memory array 150. The transistor P21 is coupled between a node of the power supply voltage VDDM and the sources of transistors P22 and P23, and the transistor P21 has a gate for receiving the enable signal D-SAEB from a clock generator 210. The transistor N21 is coupled between a node of the power supply voltage VSS (i.e., a gorund) and the sources of transistors N22 and N23, and the transistor N21 has a gate for receiving the enable signal SAEB from the clock generator 210. The transistors P22, P23, N22 and N23 form a latch for storing the enable signal IBWEB at a node between the transistors P22 and N22, and the enable signal IBWB at a node between the transistors P23 and N23. The enable signal IBWEB is complementary to the enable signal IBWB. By using the transistors P21 and N21 and the inverter 122, the D latch circuit 116 functions as a latch with a level shifter for the write enable signal BWEB.

In some embodiments, the first latch circuit 104 may include a read gating circuit 250, a latch circuit 252, a pre-charge circuit 254, and an inverter 220 having a terminal coupled to the bypass circuit 102. The read gating circuit 250 can transmit a bypass data signal SXOR and the inverted bypass data signal SXORB inverted by the inverter 220, to the data line DL and the data line DLB, respectively, in response to enable signal D-SAEB. For illustration, the read gating circuit 250 is coupled between the data lines DL and DLB, the bypass circuit 102, and the inverter 220 of the first latch circuit 104. It should be noted that the inverter 220 is powered by the power supply voltage VDD. The read gating circuit 250 may include a first switch 112 and a second switch 114. The first switch 112 may include the transistor N3 that is coupled to the data line DL, an input terminal of the inverter 220, and the output of the XOR gate 103 of the bypass circuit 102. The first switch 112 is configured to transmit the bypass data signal SXOR from the XOR gate 103 to the data line DL in response to enable signal D-SAEB. The second switch 114 may include the transistor N4 that is coupled to the data line DLD, an output terminal of the inverter 220. The second switch 114 can be configured to transmit the inverted bypass data signal SXORB from the inverter 220 to the data line DLB in response to the enable signal D-SAEB. It should be noted that the first switch 112 and the second switch 114 should not be formed by the transmission gates or P-type transistors to prevent them from not being completely turned off due to the power supply voltage VDD being different from the power supply voltage VDDM.

The latch circuit 252 may have terminals coupled to the data lines DL and DLB. The latch circuit 252 may transfer the input states from the data lines DL and DLB to the output states when signaled (e.g., a read mode or a DFT test mode), the output thereafter remaining insensitive to changes in input status until signaled again. Alternatively stated, the first switch 112 is coupled between the bypass circuit 102 and one of the terminals of the latch circuit 252, and the second switch 114 is coupled between the inverter 220 and another terminal of the latch circuit 252. For illustration, the latch circuit 252 may include the transistors P1, P2, P11, N1 and N2, and the transistors P1, P2 and P11 are P-type transistors and the transistors N1 and N2 are the N-type transistors. The transistor P11 is coupled to a node of the power supply voltage VDDM. The transistor P1 is coupled between the transistors P11 and N1, and the transistor P2 is coupled between the transistors P11 and N2. The transistor N1 is coupled between the transistor P1 and the first transistor 108, and the transistor N2 is coupled between the transistor P2 and the second transistor 110. The first transistor 108 and the second transistor 110 can be N-type transistors. The first transistor 108 is coupled to a node of the power supply voltage VSS (e.g., providing ground potential) and configured to operate in response to a sense enable signal SAE from the clock generator 210. The sense enable signal SAE is referred to as a periodic signal for enabling the first latch circuit 104 (e.g., sense amplifier) for a certain mode (e.g., a read mode or a DFT test mode). The first transistor 108 can be gated by the sense enable signal SAE. The second transistor 110 is coupled to a node of the power supply voltage VSS and configured to operate in response to a clock signal DCK. The clock signal DCK is referred to as a periodic signal for enabling the first latch circuit 104 (e.g., sense amplifier) for a certain mode (e.g., a write mode). The second transistor 110 can be gated by the clock signal DCK. The transistors N1 and Pl form an inverter that is cross-coupled with an inverter formed by the transistors N2 and P2.

The pre-charge circuit 254 is coupled to the data lines DL and DLB. In some embodiments, during the test mode, the pre-charge circuit 254 is configured to be turned off in response to a pre-charge enable signal DLEQB having a high logic level when the enable signal SAE has the low logic level. The relationship between the pre-charge enable signal DLEQB and each mode is shown in FIG. 3B. In some embodiments, the pre-charge circuit 254 may include P-type transistors P3-P5 having control terminal receiving the pre-charge enable signal DLEQB. Specifically, the transistor P3 is coupled between the data line DL and the node of the power supply voltage VDDM, and the transistor P4 is coupled between the data line DLB and the node of the power supply voltage VDDM. The transistor P5 is coupled between the data lines DL and DLB.

The first latch circuit 104 further includes the P-type transistors P12 and P13. The transistor P12 is coupled between the data line DL and the bit line BL, and the transistor P13 is coupled between the data line DLB and the bit line BLB. The transistors P12 and P13 are controlled by the signal RCS. The signal RCS has the high logic level (“1”) in the non-read mode. The relationship between the signal RCS and each mode is shown in FIG. 3C.

The second latch circuit 106 (e.g., output latch circuit) may include P-type transistors P6-P9, N-type transistors N5-N8, and a NAND gate 222. The second latch circuit 106 is configured to transfer the output states from the latch circuit 252 to the inverter 212 when signaled (e.g., a read mode or a DFT test mode), and the second latch circuit 106 may retain the output state even after removing the input (e.g., the output states from the latch circuit 252). In the embodiment of FIG. 2, the second latch circuit 106 may further includes the inverter 212. In some embodiments, the transistor P6 is coupled between a node of the power supply voltage VDDM and the transistor P7. The transistor P7 is coupled between the transistors P6 and N5. Furthermore, a drain of the transistor P7 is further coupled to the transistors N7 and P9, an input terminal of the inverter 212, and a first input terminal of the NAND gate 222. The transistor N6 is coupled between a node of the power supply voltage VSS and the transistor N5. The transistor P8 is coupled between a node of the power supply voltage VDDM and the transistor P9. The transistor N8 is coupled between a node of the power supply voltage VSS and the transistor N7. The transistors N6 and P6 have control terminals coupled to the data line DLB and are configured to operate in response to a data signal of the data line DLB. The transistors P7 and N7 are configured to be switched in response to the enable signal SAEB from the clock generator 210. The transistors P9 and N5 are configured to be switched in response to the enable signal SAE from the clock generator 210, and the control terminals of the transistors P9 and N5 are coupled to the control terminal of the transistor N3. Control terminals of the transistors P8 and N8 are coupled to the output of the NAND gate 222. The NAND gate 222 may receive an enable control signal PMB (having a complementary logic level to the enable control signal PM). In some embodiments, the memory device 100 further includes a write control circuit 251 that are coupled to the latch circuit 252 in order to operate under different operation modes.

The write control circuit 251 may capture data from a temporary storage source (e.g., the latch circuit 252 or the second latch circuit 106) through the data lines DL and DLB. The latch circuit 252 may provide signals through the data lines DL and DLB. These signals may control the transistor columns, influencing voltages of the bit line BL and the bit line BLB, which are converted to binary signals for the write control circuit 251. In this configuration, the write-in latch holds the data of the data line DL during a clock cycle for writing into memory cells. During a read operation (e.g., a write clock WCLK=1 (non-write mode)), the write-in latch is largely inactive. The relationship between the write clock WCLK and each mode is shown in FIG. 3D. The write control circuit 251 may the NOR gates 221 and 222, a write truth transistor WT, and a write complement transistor WC. The transistors WT and WC are N-type transistors. The NOR gate 221 is configured to generate a control signal to control the transistor WC according to the write clock WCLK, the data of the data line DL, and the control signal IBWEB from the D latch circuit 116. Furthermore, the NOR gate 223 is configured to generate a control signal to control the transistor WT according to the write clock WCLK, the data of the data line DLB, and the control signal IBWEB from the D latch circuit 116. These signals generated by the NOR gates 221 and 223 activate the transistors WC and WT, respectively, writing to the bit line BL and the bit line BLB, which are complementary signals. This configuration facilitates writing operations based on inputs, enabling data storage in corresponding locations. In other words, the write control circuit 251 is coupled to the bit lines BL and BLB, and is configured to control voltages of the bit lines BL and BLB in the write mode according to voltages of the data lines DL and DLB and the the control signal IBWEB.

The I/O circuit 160 further includes the clock generator 210 including inverters 236, 238, and 242, and NOR gates 240 and 244. The NOR gate 240 is coupled between the inverter 238 and the inverter 242 (or the NOR gate 244). Specifically, the inverter 236 is configured to invert a signal GLB_SAE from an input terminal 306 to generate the enable signal SAEB. The relationship between the signal GLB_SAE and each mode is shown in FIG. 3E. The inverter 238 is configured to invert the enable signal SAEB to generate the enable signal SAE. The NOR gate 240 is configured to generate the enable signal D-SAEB based on the enable signal SAE and a signal GLB_DCK from an input terminal 302. In some embodiments, the signal GLB_DCK has the low logic level (“0”) in the test mode, and has the high logic level (“1”) in other operational mode (e.g., read mode). The relationship between the signal GLB_DCK and each mode is shown in FIG. 3F. The inverter 242 is configured to generate the enable signal D-SAE based on the enable signal D-SAEB. In the test mode, the enable signal D-SAEB is referred to as a delayed signal with respect to the enable signal SAEB, and the enable signal D-SAE is referred to as a delayed signal with respect to the enable signal SAE. In some embodiments, the NOR gate 240 is configured to generate the enable signal D-SAEB based on the enable signal SAE and the signal GLB_DCK. The NOR gate 244 is configured to generate a clock signal DCK based on the enable signal D-SAEB and a signal IWEB. The relationship between the signal IWEB and each mode is shown in FIG. 3G. The clock generator 210 can be an electronic circuit that produces a regular and repeating electrical signal known as a clock signal (e.g., enable signal SAE, clock signal DCK). The signal can be used to synchronize the operations of digital component in various devices (e.g., the latch circuit 252 or the second latch circuit 106). The clock generator 210 ensures that different parts of a system work together in a coordinated manner.

The I/O circuit 160 may further include a NOR gate 224 and inverters 226 and 228. The NOR gate 224 may have a first input coupled to the inverter 212 and a second input receiving the test enable signal DFTB. In some embodiments, the latch circuit 252 and the second latch circuit 106 (e.g., output latch circuit) are referred to as a read path D-flip-flop. Accordingly, for a scan-based testing during the SHIFT mode of the test mode, a data output signal generated by the second latch circuit 106 is transmitted through the NOR gate 224 and the inverters 226 and 228 as an input signal (e.g., the data signal D) in the following I/O circuit 160.

The I/O circuit 160 may further include the transmission gates 230 and 232 configured to operate in response to control signals HIT and HITB that have complementary logic levels. In some embodiments, the transmission gate 230 is coupled between the output of the inverter 212 and a NOR gate 234. The NOR gate 234 has a first input receiving the signal from the transmission gate 230 and a second input receiving an enable control signal PM, and is configured to generate the output signal Q to the output terminal 142.

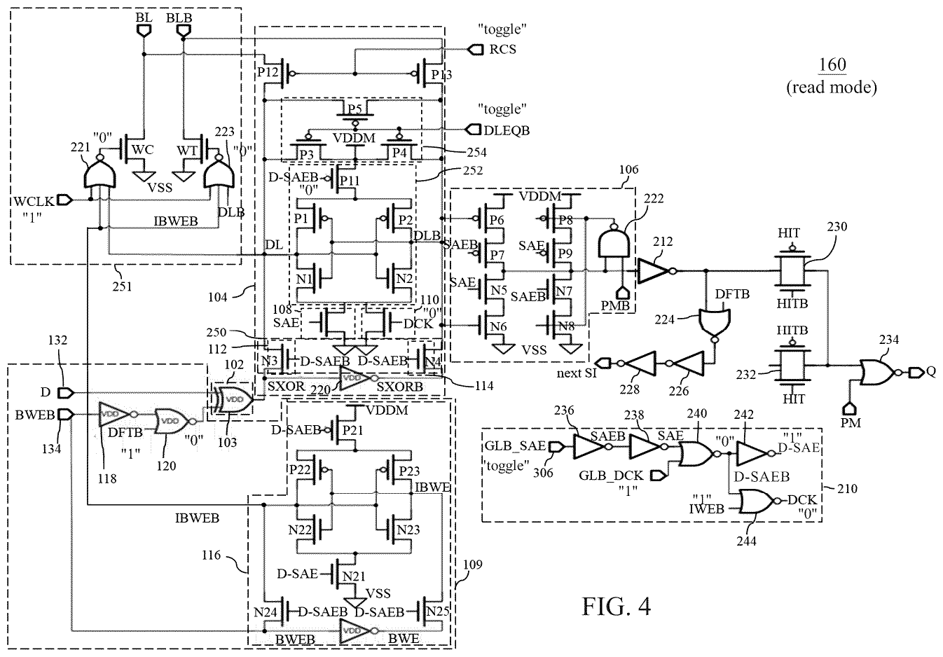

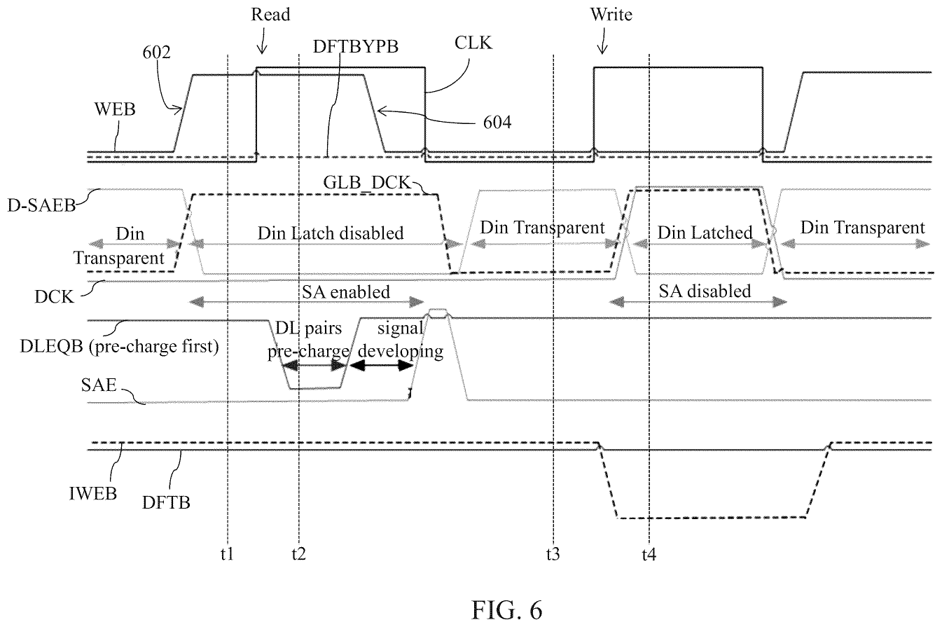

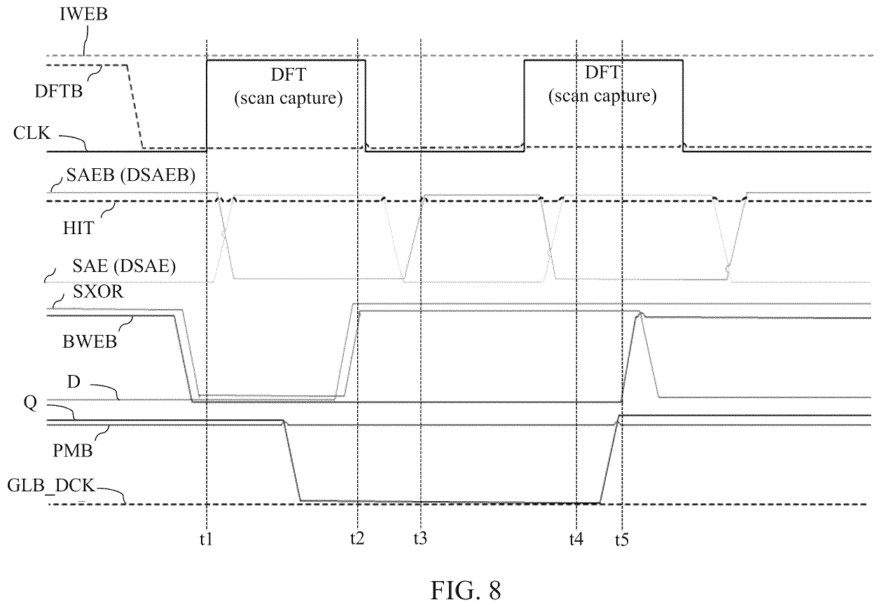

The configurations of FIG. 2 are given for illustrative purposes. Various implements are within the contemplated scope of the present disclosure. The operations of the I/O circuit 160 of FIG. 2 is substantially similar to the operations of the I/O circuit 160 of FIG. 1. The detailed operational configurations of the I/O circuit 160 in the memory device 100 of FIGS. 1 and 2 will be descripted in the following paragraphs with reference to FIGS. 4-8. FIG. 6 illustrates waveforms of signals in the I/O circuit 160 in FIGS. 1-4, in accordance with some embodiments of the present disclosure. FIG. 8 illustrates waveforms of signals in the memory device 100 in FIGS. 1-2, and 7, in accordance with some embodiments of the present disclosure.

FIG. 4 illustrates a detailed schematic diagram of the I/O circuit 160 of FIGS. 1 and 2 in a read mode, in accordance with some embodiments of the present disclosure. In the read mode, the test enable signal DFTB 148 can be set at a high logic level “1”, which causes the NOR gate 120 to output a low logic level “0”. The XOR gate 103 may receive the data signal D and the output “0” of the NOR gate 120. In the embodiment of FIG. 4, the XOR gate 103 may generate the bypass data signal SXOR (i.e., the data signal D), and may transmit the bypass data signal SXOR to the first latch circuit 104. When the I/O circuit 160 is in the read mode, the second transistor 110, the first switch 112, and the second switch 114 are deactivated (i.e., turned off), and the first transistor 108 is activated (i.e., turned on).

In the read mode, the signal GLB_DCK, the signal IWEB, the test enable signal DFTB are set to a high logic level (“1”), while the signals GLB_SAE and RCS may toggle, simulating a normal read operation. In the read mode, the first latch circuit 104, acting as a sense amplifier, is triggered at the exact timing as in a normal read operation. The D latch circuit 116 (i.e., BWEB latch) can be latched during the read operation. The data line pairs (i.e., the data lines DL and DLB) are pre-charged first in response to the pre-charge enable signal DLEQB. Specifically, the bit line BL is developed, followed by the later activation of a read-column-select to propagate the data to the data line DL.

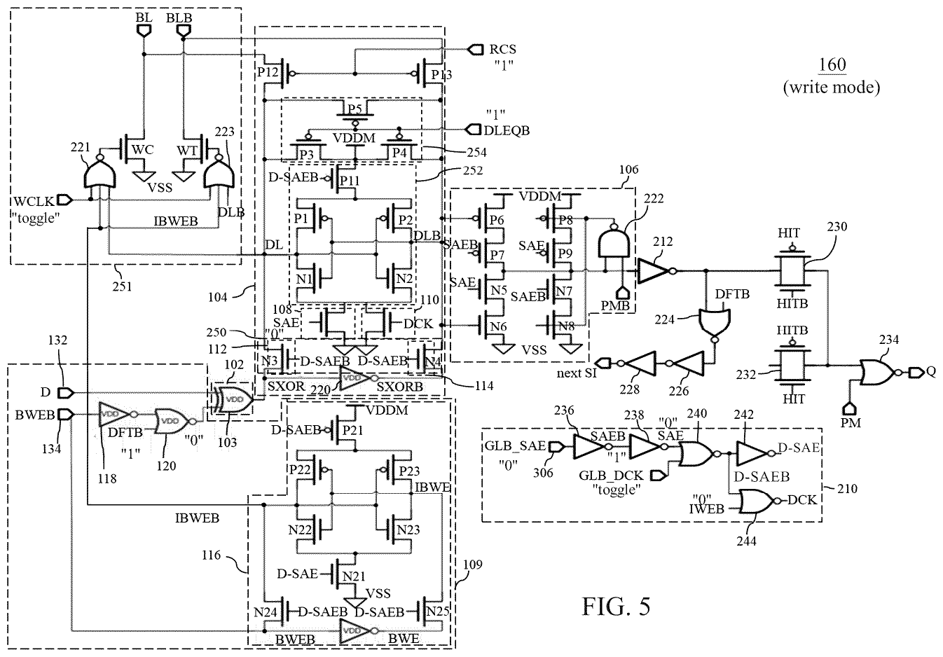

FIG. 5 illustrates a detailed schematic diagram of the I/O circuit 160 of FIGS. 1 and 2 in a write mode, in accordance with some embodiments of the present disclosure. In a write mode, the test enable signal DFTB can be set at a high logic level “1” which causes the NOR gate 120 output a low logic level “0”. The XOR gate 103 may receive the data signal D and the output “0” of the NOR gate 120. In the embodiment of FIG. 5, the XOR gate 103 may generate the bypass data signal SXOR (i.e., the data signal D), and may transmit the bypass data signal SXOR to the first latch circuit 104. When the I/O circuit 160 is in the write mode, the first transistor 108 is deactivated (i.e., turned off), and the second transistor 110, the first switch 112, and the second switch 114 are activated (i.e., turned on). The first switch 112 and the second switch 114, gated by the D-Enable signal SAE, may propagate the bypass data signal SXOR (i.e., the data signal D) and the inverted bypass data signal SXORB (i.e., the data signal bar DB) into the first latch circuit 104 (i.e., the sense amplifier).

In the write mode, the signal GLB_SAE and the signal IWEB are set to a low logic level (“0”), while the test enable signal DFTB is set to a high logic level (“1”). The signal GLB_DCK may toggle, simulating a normal write operation. In the write mode, the sense enable signal SAE is set to a low logic level “0” and the enable signal SAEB is set to a high logic level “1”, and the second latch circuit 106 (e.g., the Q-latch) may retain/latch the read-out data from the previous read cycle, ensuring its preservation. The pre-charge circuit 254 (e.g., the DL pre-chargers) is turned off in response to the pre-charge enable signal DLEQB set to a high logic level “1”. The first latch circuit 104 (e.g., the sense amplifier) may function as a data-in latch during a write operation.

The output (i.e., the enable signal IBWEB) of the D latch circuit 116 (e.g., the BWEB latch) and the data lines DL and DLB together may form a write circuit, which is gated by the write clock WCLK signal to control the writing of data to the bit line pairs (i.e., the bit lines BL and BLB) of the write control circuit 251.

FIG. 6 illustrates waveforms of signals in the I/O circuit 160 in FIGS. 4 and 5, in accordance with some embodiments of the present disclosure. The principle of operation of the I/O circuit 160 can be explained by using a timing diagram as shown in FIG. 6. In general, a cycle may include a read operation to be followed by a write operation, and the transistors of the latch circuit 252 (e.g. P1, P2, N1 and N2) are first pre-charged before every read operation.

At time t1, the pre-charge circuit 254 may pre-charge the data lines DL and DLB in response to a pre-charge enable signal DLEQB having a high level when the enable signal SAE has a low level. After a period of pre-charge, the signals (e.g., enable signal SAE or DCK signal) may turn on the first transistor 108 and the second transistor 110 later since the first transistor 108 and the second transistor 110 may take time to recharge. The enable signal D-SAEB is set to a low level during the phase where the latch circuit 252 is disabled. The voltage level of a write enable signal WEB during a rising clock edge 602 triggers the start of a read operation or a write operation. In the embodiment of FIG. 6, at a first rising clock edge 602, the WEB signal is set to a high level to trigger a read operation during which the transistors of the first latch circuit 104 (i.e., the sense amplifier circuit) is enabled.

At time t2, the pre-charge enable signal DLEQB is then set to a low level after the pre-charge has finished. During a read operation, the clock signal DCK and the enable signal D-SAEB may remain a low level. The enable signal SAE may momentarily go to a high level to activate a sensing function of the first latch circuit 104 (i.e., the sense amplifier circuit). After the sensing function has been performed, the enable signal SAE may go to a low level and remain low during the write operation. The clock signal DCK is at a low logic throughout the read operation, and the enable signal SAE is also set to a low level at the beginning of a read cycle. The voltage level of the write enable signal WEB during the rising clock edge 602 triggers the start of the read operation. At the end of the read operation, the enable signal SAE is then momentarily set to a high level to perform sensing of the differential signals (e.g. the signals of the data lines DL and DLB) so as to sense the binary value. As the enable signal SAE goes down to a low level, the enable signal D-SAEB is set to a high level while the data Din of the data line DL is at a transparent phase. After the read operation is finished, the write operation may begin. At a second rising clock edge 604, the write enable signal WEB is set to a low level to trigger a write operation during which the transistors of the first latch circuit 104 (i.e., the sense amplifier circuit) are disabled throughout.

At time t3, before a data is latched during a write operation, the data Din may go through a period during which the data Din is considered transparent and the enable signal D-SAEB is set to a high level. In further detail, the pre-charge enable signal DLEQB is first set to a high level in order to turn on the pre-charge circuit 254 (e.g., the transistors P3, P4 and P5) to equalize and pre-charge the first latch circuit 104 (i.e., the sense amplifier circuit). The enable signal D-SAEB is set to a high level during the phase where the data Din is transparent. From the end of a read operation to the start of a write operation, the pre-charge enable signal DLEQB may go up to a high voltage in order to turn on the pre-charge circuit 254 and pre-charge the first latch circuit 104 (i.e., the sense amplifier circuit) throughout the write operation. The pre-charge enable signal DLEQB remains at a high level until the beginning of the next cycle, and the enable signal SAE also remains at a low level throughout the write operation since the first latch circuit 104 (i.e., the sense amplifier circuit) may not be needed during the write operation except to latch the data Din. In order to latch the data Din, the clock signal DCK may momentarily set to a high level to perform sensing of the differential signals (e.g. the data lines DL and DLB) so as to sense the binary value and also to latch the binary value stored in the latch circuit 252.

At time t4, while the data Din is latched, the clock signal DCK is set to a high level. At the start of the write operation, the enable signal D-SAEB is set to a high level while the data Din is at a transparent phase. While the data Din is being latched, the enable signal D-SAEB may go to a low level as the relationship between the enable signal D-SAEB and the clock signal DCK are complementary during a write operation. After the write operation is finished, another cycle of a read operation to be followed by a write operation may begin.

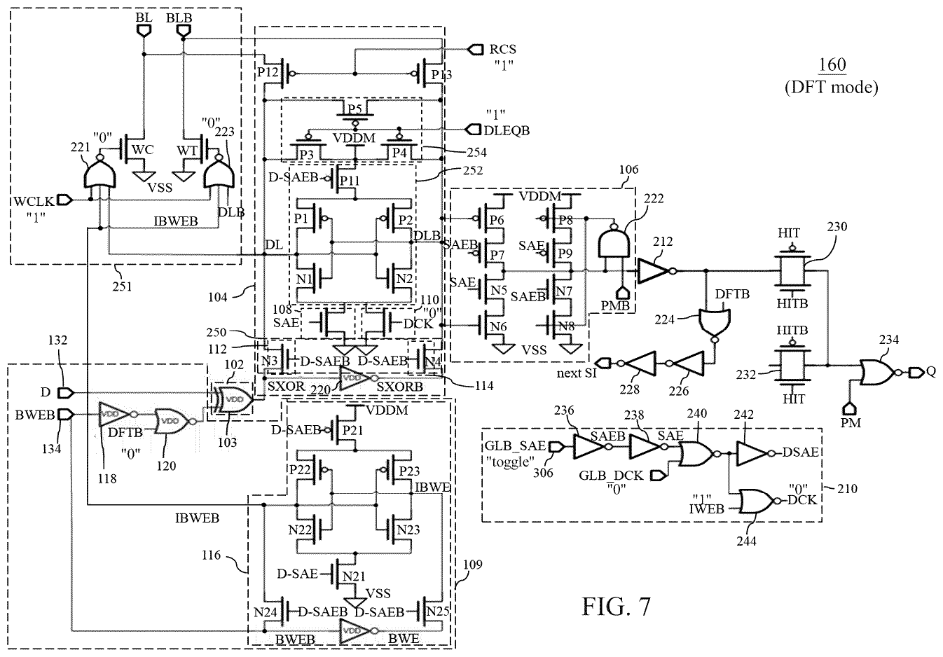

FIG. 7 illustrates a detailed schematic diagram of the I/O circuit 160 of FIGS. 1 and 2 in a DFT test mode, in accordance with some embodiments of the present disclosure.

In the DFT test mode, the test enable signal DFTB can be set at a low logic level “0”, which causes the NOR gate 120 output the write enable signal BWEB. The XOR gate 103 may receive the data signal D and the write enable signal BWEB. In such case, the XOR gate 103 may generate the bypass data signal SXOR, and may transmit the bypass data signal SXOR to the first latch circuit 104. When the the I/O circuit 160 is at a DFT test mode, the first transistor 108, the first switch 112, and the second switch 114 are activated (i.e., turned on), and the second transistor 110 is deactivated (i.e., turned off). The first switch 112 and the second switch 114, each gated by the enable signal D-SAEB, may propagate the data signal XOR and data signal bar XORB into the first latch circuit 104 (i.e., the sense amplifier).

In the DFT test mode, the signal GLB_DCK and the test enable signal DFTB are set to a low logic state (“0”), while the signal IWEB is set to a high logic level (“1”). The signal GLB_SAE may toggle as a single clock source for a DFT D flip-flop. The pre-charge enable signal DLEQB is set to a high logic level (“1”), disabling the pre-chargers of the data lines DL and DLB. While the D latch circuit 116 (e.g., BWEB latch) may toggle, the write behavior is deactivated. The first latch circuit 104 (e.g., sense amplifier) may function as a master latch during a DFT operation. The second latch circuit 106 may function as a shadow latch in a DFT D flip-flop. The first latch circuit 104 and the second latch circuit 106 collectively operate as a data flip-flop (e.g., D-flip-flop) in the DFT test mode. It may not be necessary to retain the previously read-out data during the DFT test mode.

FIG. 8 illustrates waveforms of signals in the I/O circuit 160 in FIG. 7, in accordance with some embodiments of the present disclosure. The principle of DFT test operation of the I/O circuit 160 can be explained by using a timing diagram as shown in FIG. 8. In a DFT test mode, the test enable signal DFTB can be set to a low logic level “0”. The write enable signal BWEB changes to the low logic level and accordingly the XOR gate 103 generates the bypass data signal XOR to have the low logic level when the data signal D has the low logic level.

At time t1, as a global clock signal CLK for the I/O circuit 160 is set to a high level, the NOR gate 120 generates the enable signal D-SAEB having the low logic level in response to the enable signal SAE rising to have the high logic level and the test enable signal DFTB having the low logic. The inverter 242 may invert the enable signal D-SAEB to generate the enable signal D-SAE having the high logic level.

From time t1 to time t2, the data signal D is inputted and rises to have a high logic level. The XOR gate 103 generates and transmits the bypass data signal XOR having the high logic level at time T2 to the first latch circuit 104 (i.e., the sense amplifier).

At time t3, in the test mode, the read gating circuit 250 is turned on to transmit the bypass data signal XOR to the latch circuit 252, in response to the enable signal D-SAEB having the high logic level and the enable signal D-SAE having the low logic level, when the second latch circuit 106 is turned off in response to the enable signal SAE having the low logic level and the enable signal SAEB having the high logic level. Specifically, the bypass data signal SXOR having the high logic level is transmitted to the data line DL through the first switch 112, and the bypass data signal SXORB having the low logic level is transmitted to the data line DLB through the second switch 114. Accordingly, during the test mode, the first latch circuit 104 adjusts voltage levels of the data lines DL and DLB according to the bypass data signal SXOR, corresponding to the data signal D, in response to the enable signal SAE having the low logic level and the enable signal D-SAEB having the high logic level.

At time T4, the second latch circuit 106 is turned on in response to the enable signal SAE rising to have the high logic level and the enable signal SAEB having the low logic level. Specifically, the transistor P6 is turned on in response to the data line DLB having a low voltage level corresponding to the bypass data signal SXORB, and transmits the supply voltage VDDM through the turned-on transistor P7 responsive to the enable signal SAEB. Accordingly, the second latch circuit 106 generates a data output signal by the inverter 212 therein, in which the data output signal has the low logic level.

At time t5, the transmission gate 230 transmits the data output signal with the low logic level, in response to the control enable signal HIT having the high logic level and the control enable signal HITB having the low logic level, to the NOR gate 234. The NOR gate 234 generates the output signal Q having the high logic level in response to the enable control signal PM having the low logic level and the data output signal having the low logic level. Accordingly, the output signal Q and the data signal D have the same logic state. Alternatively stated, the data of the data signal D is latched by the first latch circuit 104 and the second latch circuit 106, and is transmitted as the output signal Q in the test mode.

With the configurations of the present disclosure, the first latch (i.e., the sense amplifier) 104, reading out data from the memory cells in the read mode, and the second latch (i.e., Q latch circuit) circuit 106, latching the read data temporarily for further operations, are configured to scan capture or shift test data in the test mode, which achieves area and power saving as no extra D flip-flop circuit, shadow latches, level shifter, and/or other associated logic circuit are necessary to be equipped. Furthermore, based on the reasons above, leakage in the memory device is remedied along with reduced number of circuits and logic gates.

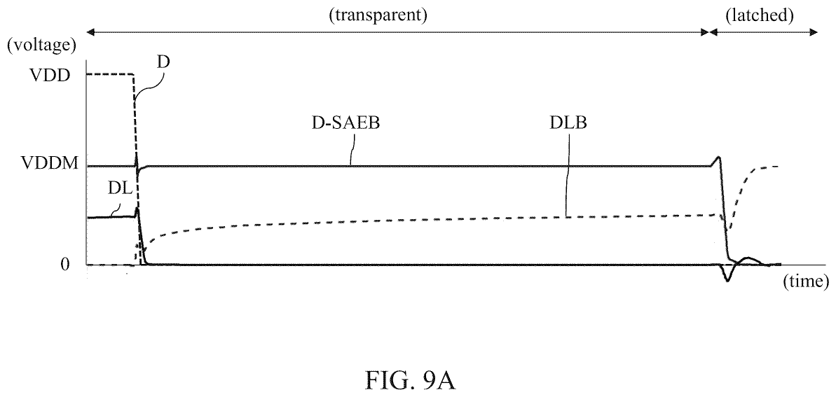

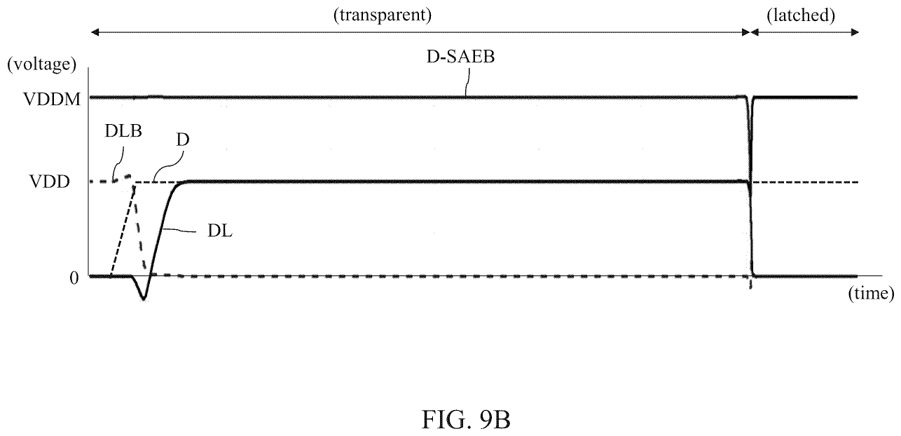

FIGS. 9A and 9B illustrates waveforms of signals propagating from VDD domain to VDDM domain in the I/O circuit 160 in FIG. 7, in accordance with some embodiments of the present disclosure.

In FIG. 9A, the power supply voltage VDD is greater than the power supply voltage VDDM. When the enable signal D-SAEB is at a high level (i.e., the power supply voltage VDDM), the first latch circuit 104 (i.e., the sense amplifier) is at a transparent period, and when the enable signal D-SAEB is at a low level (i.e., the power supply voltage VSS (0V)), the first latch circuit 104 (i.e., the sense amplifier) is at a latched period. During the transparent period, the data signal D is changed from a high level (i.e., the power supply voltage VDD) to a low level (i.e., the power supply voltage VSS (0V)). In response to the enable signal D-SAEB, the data signal D (e.g., the bypass data signal SXOR) and its complementary signal (e.g., the bypass data signal SXORB) are transmitted to the data lines DL and DLB through the first switch 112 and the second switch 114, respectively. It should be noted that the data lines DL and DLB and the control signals IBWE and IBWEB may have a partial level of the power supply voltage VDDM during the transparent period, e.g. up to the power supply voltage VDDM minus the threshold voltage of the first switch 112 and the second switch 114, i.e., VDDM-Vt. Therefore, during the transparent period, the voltage of the data line DLB is less than the VDDM until entering the latched period.

In FIG. 9B, the power supply voltage VDD is less than the power supply voltage VDDM. When the enable signal D-SAEB is at a high level (i.e., the power supply voltage VDDM), the first latch circuit 104 (i.e., the sense amplifier) is at the transparent period, and when the enable signal D-SAEB is at a low level (i.e., the power supply voltage VSS (0V)), the first latch circuit 104 (i.e., the sense amplifier) is at the latched period. During the transparent period, the data signal D is changed from a low level (i.e., the power supply voltage VSS (0V)) to a high level (i.e., the power supply voltage VDD). In response to the enable signal D-SAEB, the data signal D (e.g., the bypass data signal SXOR) and its complementary signal (e.g., the bypass data signal SXORB) are transmitted to the data lines DL and DLB through the first switch 112 and the second switch 114, respectively. In the embodiment of FIG. 9B, because a voltage difference between the power supply voltages VDDM and VDD is greater than the threshold voltage of the first switch 112 and the second switch 114, the data lines DL and DLB and the control signals IBWE and IBWEB may have a level of the power supply voltage VDD during the transparent period. Therefore, during the transparent period, the voltage of the data line DL is less than the VDDM until entering the latched period.

In the I/O circuit 160, when the first latch circuit 104 (i.e., the sense amplifier) is at the transparent period, the data lines DL and DLB having the partial level of the power supply voltage VDDM will not cause leakage because the write clock WCLK, the enable signal SAEB, the pre-charge enable signal DLEQB, and the signal RCS all hold at the power supply voltage VDDM, allowing complete isolation without leakage paths. For example, in response to the write clock WCLK having the power supply voltage VDDM, the NOR gates 221 and 222 are configured to generate the output signals having a low level. In other words, the NOR gates 221 and 222 are controlled by the write clock WCLK, thus preventing the control signal IBWEB with the partial level of the power supply voltage VDDM from causing leakage paths in the l NOR gates 221 and 222. Furthermore, the data lines DL and DLB are coupled to the drain sides of transistors P3-P5 of the pre-charge circuit 254 and the transistors P12 and P13, and the transistorsP3-P5 and P12-P13 are turned off due to gate to the power supply voltage VDDM. Therefore, no leakage path is present due to the maximum voltage of the data lines DL and DLB is equal to the power supply voltage VDDM minus the threshold voltage of the first switch 112 and the second switch 114.

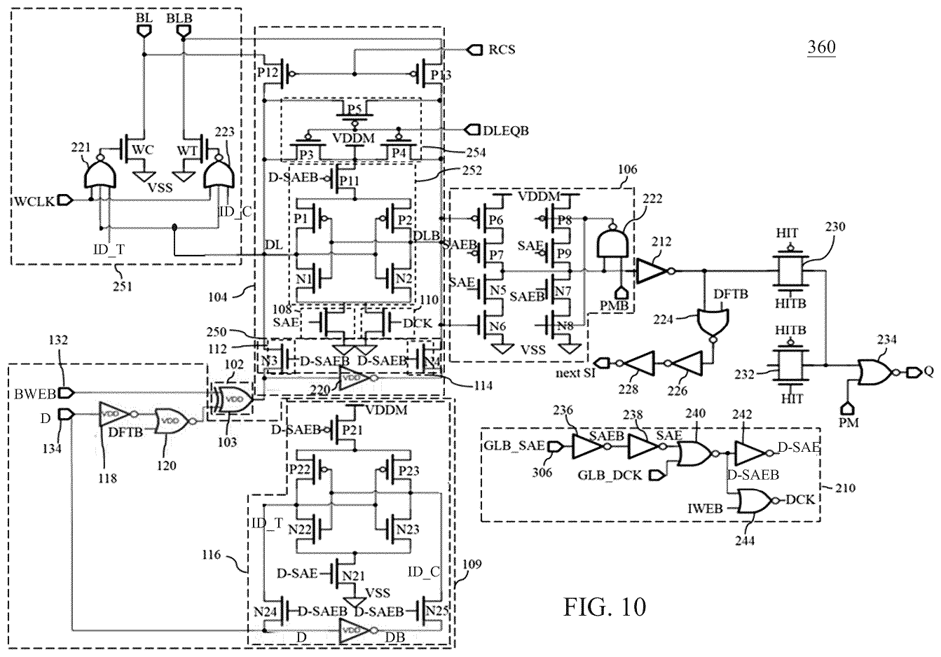

FIG. 10 illustrates a detailed schematic diagram of the I/O circuit 360, in accordance with some embodiments of the present disclosure. The I/O circuit 360 of FIG. 10 is substantially similar to the I/O circuit 160 of FIG. 2, except that the input terminal 132 is configured to receive the write enable signal BWEB, and the input terminal 134 is configured to receive the data signal D. The D latch circuit 116 may be configured to receive the data signal D and provide the control signals ID_T and ID_C to the write control circuit 251. The bypass circuit 102 is configured to provide the output according to the write enable signal BWEB to the read gating circuit 250. The specific operations of similar elements, which are already discussed in detail in above paragraphs, are omitted herein for the sake of brevity.

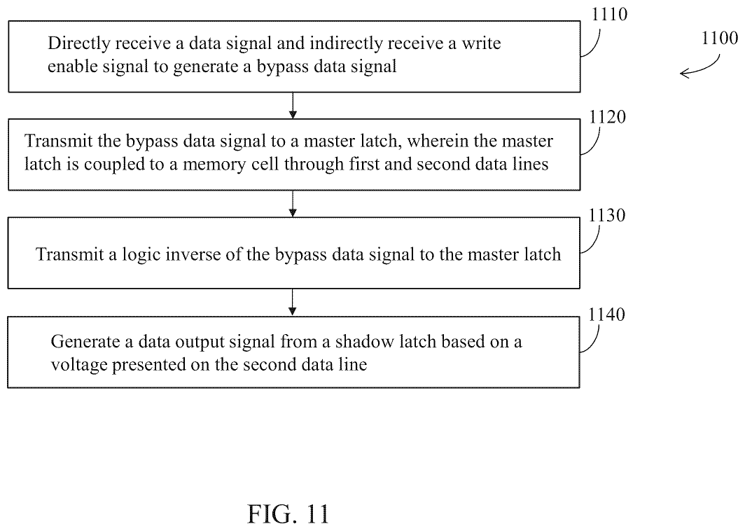

FIG. 11 is a flowchart of a method 1100 for operating the I/O circuit 160 of FIGS. 1 and 2, in accordance with some embodiments of the present disclosure. The method 1100 may be used to operate the memory device 100. For example, at least some of the operations described in the method 1100 can be performed during a test mode for the memory device 100. It is noted that the method 1100 is merely an example and is not intended to limit the present disclosure. Accordingly, it is understood that additional operations may be provided before, during, and after the method 1100 of FIG. 11, and that some other operations may only be briefly described herein.

The method 1100 starts with operation 1110 in which the I/O circuit 160 may directly receive a data signal D and indirectly receive a write enable signal BWEB to generate a bypass data signal SXOR. For example, in FIG. 2, the bypass circuit 102 may directly receive the data signal D and indirectly receive the write enable signal BWEB. The bypass circuit 102 may generate an XOR output SXOR according to the directly received data signal D and the indirectly received write enable signal BWEB.

The method 1100 continues to operation 1120 in which the I/O circuit 160 may transmit the bypass data signal SXOR to a first latch (master latch) 104. The first latch circuit 104 is coupled to a memory cell through a first bit line 138 and a second bit line 140. Continuing with the above example in FIG. 2, the XOR gate 103 may transmit the bypass data signal SXOR to the first latch circuit 104.

The method 1100 continues to operation 1130 in which the I/O circuit 160 may transmit a logic inverse of the bypass data signal SXOR to the first latch (master latch) 104. The master latch circuit 104 includes a sense amplifier coupled to a first transistor 108 and a second transistor 110. The first transistor 108 gated by a sense enable signal SAE and the second transistor 110 gated by a clock signal DCK. Continuing with the above example in FIG. 2, the inverter 220 of the first latch circuit 104 may generate an inverted bypass data signal SXORB according to the bypass data signal SXOR. The second switch 114 may transmit the inverted bypass data signal SXORB from the inverter 220 to the data line DLB. The first transistor 108 can be coupled to the first latch circuit 104 and gated by a sense enable signal SAE. The second transistor 110 can be coupled to the first latch circuit 104 and gated by a clock signal DCK.

The method 1100 continues to operation 1140 in which the I/O circuit 160 may generate a data output signal Q based on a voltage level presented on the data line DLB from a second latch circuit 106 (i.e., shadow latch). The shadow latch 106 includes a Q latch. The master latch circuit 104 together with the shadow latch 106 operatively serve as a data flip-flop. The operations 1110-1140 are performed during a test mode for the memory device 100. Continuing with the above example in FIG. 2, the second latch circuit 106 can be configured to generate an output signal Q based on a voltage level presented on the data line DLB. The first latch circuit 104 may utilize the bypass data signal SXOR and the inverted bypass data signal SXORB as inputs to operate as a DFT D flip-flop.

The present disclosure involves the removal of components such as the write-in latch, shadow latch, 3-to-1 MUX, PM ISO clamping, and power-saving logic from the circuit. The removal results in a significant improvement in layout area utilization within every IO. Furthermore, the elimination of extra devices and transistors for the write-in and shadow latch, along with their related logic schemes, contributes to a notable reduction in leakage. The absence of these additional circuits minimizes power consumption, as there are no extra signal toggling activities. Despite the removal of these components, the read, write, and DFT operations continue to function effectively. The Q-latch retains the last read data even during write mode, ensuring there is no performance impact. The memory design provides promising results in terms of DFT-related racing issues. Additionally, it is anticipated that the layout will benefit from an improved IO area-saving ratio in future implementations. This approach offers improved layout area utilization, reduced leakage, lower power consumption, and maintains the functionality of essential operations without performance degradation.

According to some embodiments, an input/output circuit for a memory array having a first bit line and a second bit line is provided. The input/output circuit includes a first latch circuit coupled between a first data line and a second data line, a second latch circuit coupled to the first latch circuit and configured to generate a data output signal based on a voltage of the second data line, a first transistor coupled between the first bit line and the first data line, a second transistor coupled between the second bit line and the second data line, and a bypass circuit configured to directly receive a data signal and indirectly receive a write enable signal to generate a first signal to the first latch circuit. The first latch circuit includes a first inverter having an input for receiving the first signal, a first switch coupled between the first data line and the input of the first inverter; and a second switch coupled between the second data line and an output of the first inverter. The first and second switches are activated in a write mode and a test mode and are deactivated in a read mode. The first inverter and the bypass circuit are configured to be powered by a first power supply voltage, and the memory array, the first latch circuit except the first inverter, and the second latch circuit are configured to be powered by a second power supply voltage different from the first power supply voltage.

According to some embodiments, an input/output circuit for a memory array having a first bit line and a second bit line is provided. The input/output circuit includes a bypass circuit, a first latch circuit, a second latch circuit, a first transistor, a second transistor, a third transistor, and a fourth transistor. The bypass circuit is configured to directly receive a data signal and indirectly receive a write enable signal to generate a first signal. The first latch circuit is coupled between a first data line and a second data line, and includes a first inverter having an input for receiving the first signal, a first switch coupled between the first data line and the input of the first inverter, and a second switch coupled between the second data line and an output of the first inverter. The second latch circuit is coupled to the first latch circuit and configured to generate a data output signal based on a voltage of the second data line. The first transistor is coupled to the first latch circuit and gated by a sense enable signal. The second transistor is coupled to the first latch circuit and gated by a clock signal. The third transistor is coupled between the first bit line and the first data line. The fourth transistor is coupled between the second bit line and the second data line. The first transistor and the second transistor are alternately activated in each of a plurality of operation modes including a read mode, a write mode and a test mode. The first inverter and the bypass circuit are configured to be powered by a first power supply voltage, and the memory array, the first latch circuit except the first inverter, and the second latch circuit are configured to be powered by a second power supply voltage different from the first power supply voltage.

According to some embodiments, a method for operating an input/output circuit of a memory array is provided. The method includes: directly receiving a data signal and indirectly receiving a write enable signal to generate a bypass data signal, by a bypass circuit; transmitting the bypass data signal to a first latch, wherein the first latch is coupled to the memory array through a first data line and a second data line; transmitting a logic inverse of the bypass data signal to the first latch; generating a data output signal based on a voltage presented on the second data line, by a second latch; providing a first power supply voltage to power a first inverter and the bypass circuit; and providing a second power supply voltage to power the memory array, the first latch except the first inverter, and the second latch. The second power supply voltage is different from the first power supply voltage. The first latch includes the first inverter having an input for receiving the bypass data signal, a first switch coupled between the first data line and the input of the first inverter, and a second switch coupled between the second data line and an output of the first inverter.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An input/output circuit for a memory array having a first bit line and a second bit line, comprising:
a first latch circuit coupled between a first data line and a second data line;
a second latch circuit coupled to the first latch circuit and configured to generate a data output signal based on a voltage of the second data line;
a first transistor coupled between the first bit line and the first data line;
a second transistor coupled between the second bit line and the second data line; and
a bypass circuit configured to directly receive a data signal and indirectly receive a write enable signal to generate a first signal to the first latch circuit;
wherein the first latch circuit comprises:
a first inverter having an input for receiving the first signal;
a first switch coupled between the first data line and the input of the first inverter; and
a second switch coupled between the second data line and an output of the first inverter,
wherein the first and second switches are activated in a write mode and a test mode and are deactivated in a read mode,
wherein the first inverter and the bypass circuit are configured to be powered by a first power supply voltage, and the memory array, the first latch circuit except the first inverter, and the second latch circuit are configured to be powered by a second power supply voltage different from the first power supply voltage.

2. The input/output circuit of claim 1, further comprising:
a third latch circuit configured to latch the write enable signal to generate a second signal; and
a write control circuit coupled to the first and second bit lines, and configured to control voltages of the first and second bit lines in the write mode according to voltages of the first and second data lines and the second signal.

3. The input/output circuit of claim 2, wherein the third latch circuit comprises:
a second inverter having an input for receiving the write enable signal;
a first P-type transistor coupled to a node of the second power supply voltage;
a second P-type transistor and a third P-type transistor coupled to the first P-type transistor;
a first N-type transistor coupled to a ground;
a second N-type transistor coupled between the first N-type transistor and the second P-type transistor;
a third N-type transistor coupled between the first N-type transistor and the third P-type transistor, wherein drains of the second N-type and P-type transistors are coupled to gates of the third N-type and P-type transistors, and drains of the third N-type and P-type transistors are coupled to gates of the second N-type and P-type transistors;
a fourth N-type transistor coupled between the input of the second inverter and the drains of the second N-type and P-type transistors; and
a fifth N-type transistor coupled between an output of the second inverter and the drains of the third N-type and P-type transistors,
wherein the second inverter is configured to be powered by the first power supply voltage, and the second signal is generated in the drains of the second N-type and P-type transistors.

4. The input/output circuit of claim 2, wherein the write control circuit comprises:
a first N-type transistor coupled between the first bit line and a ground;
a second N-type transistor coupled between the second bit line and the ground;
a first NOR gate configured to provide a first control signal to a gate of the first N-type transistor according to a write clock, a voltage of the first data line, and the second signal; and
a second NOR gate configured to provide a second control signal to a gate of the second N-type transistor according to the write clock, the voltage of the second data line, and the second signal,
wherein the write clock is set to the second power supply voltage in the test mode and the read mode.

5. The input/output circuit of claim 1, further comprising:
a first N-type transistor coupled to the first latch circuit and gated by a sense enable signal; and
a second N-type transistor coupled to the first latch circuit and gated by a clock signal,
wherein the first N-type transistor is deactivated by the sense enable signal in the write mode, and the second N-type transistor is deactivated by the clock signal in the read mode and the test mode.

6. The input/output circuit of claim 5, wherein the first latch circuit and the second latch circuit collectively operate as a data flip-flop in the read mode and test mode where the clock signal is disabled and the sense enable signal toggles as a clock source for the data flip-flop.

7. The input/output circuit of claim 1, wherein the bypass circuit includes an XOR gate having a first input configured to receive the data signal and a second input configured to receive the write enable signal at least through a second inverter and a NOR gate, wherein the XOR gate, the second inverter and the NOR gate are configured to be powered by the first power supply voltage.

8. The input/output circuit of claim 7, wherein the NOR gate has a first input configured to receive a control signal and a second input coupled to an output of the second inverter, wherein the control signal is set to the first power supply voltage in the read mode and the write mode, and the control signal is set to a grounding voltage in the test mode.

9. The input/output circuit of claim 1, wherein each of the first and second switches comprises an N-type transistor.

10. The input/output circuit of claim 1, wherein each of the first and second transistors comprises a P-type transistor controlled by a control signal, and the control signal is set to the second power supply voltage in the test mode and the write mode, and the control signal is configured to toggle as a clock in the read mode.

11. An input/output circuit for a memory array having a first bit line and a second bit line, comprising:
a bypass circuit configured to directly receive a data signal and indirectly receive a write enable signal to generate a first signal;
a first latch circuit coupled between a first data line and a second data line, and comprising:
a first inverter having an input for receiving the first signal;
a first switch coupled between the first data line and the input of the first inverter; and
a second switch coupled between the second data line and an output of the first inverter;
a second latch circuit coupled to the first latch circuit and configured to generate a data output signal based on a voltage of the second data line;
a first transistor coupled to the first latch circuit and gated by a sense enable signal;
a second transistor coupled to the first latch circuit and gated by a clock signal;
a third transistor coupled between the first bit line and the first data line; and
a fourth transistor coupled between the second bit line and the second data line,
wherein the first transistor and the second transistor are alternately activated in each of a plurality of operation modes comprising a read mode, a write mode and a test mode,
wherein the first inverter and the bypass circuit are configured to be powered by a first power supply voltage, and the memory array, the first latch circuit except the first inverter, and the second latch circuit are configured to be powered by a second power supply voltage different from the first power supply voltage.

12. The input/output circuit of claim 11, wherein the first and second switches are activated in the write mode and the test mode, and the first and second switches are deactivated in the read mode.

13. The input/output circuit of claim 11, wherein each of the first and second switches and the first and second transistors comprises an N-type transistor, and each of the third and fourth transistors comprises a P-type transistor.

14. The input/output circuit of claim 11, further comprising:
a third latch circuit configured to latch the write enable signal to generate a second signal; and
a write control circuit coupled to the first and second bit lines, and configured to control voltages of the first and second bit lines in the write mode according to voltages of the first and second data lines and the second signal.

15. The input/output circuit of claim 14, wherein the third latch circuit comprises:
a second inverter having an input for receiving the write enable signal;
a first P-type transistor coupled to a node of the second power supply voltage;
a second P-type transistor and a third P-type transistor coupled to the first P-type transistor;
a first N-type transistor coupled to a ground;
a second N-type transistor coupled between the first N-type transistor and the second P-type transistor;
a third N-type transistor coupled between the first N-type transistor and the third P-type transistor, wherein drains of the second N-type and P-type transistors are coupled to gates of the third N-type and P-type transistors, and drains of the third N-type and P-type transistors are coupled to gates of the second N-type and P-type transistors;
a fourth N-type transistor coupled between the input of the second inverter and the drains of the second N-type and P-type transistors; and
a fifth N-type transistor coupled between an output of the second inverter and the drains of the third N-type and P-type transistors,
wherein the second inverter is configured to be powered by the first power supply voltage, and the second signal is generated in the drains of the second N-type and P-type transistors.

16. The input/output circuit of claim 14, wherein the write control circuit comprises:
a first N-type transistor coupled between the first bit line and a ground;
a second N-type transistor coupled between the second bit line and the ground;
a first NOR gate configured to provide a first control signal to a gate of the first N-type transistor according to a write clock, a voltage of the first data line, and the second signal; and
a second NOR gate configured to provide a second control signal to a gate of the second N-type transistor according to the write clock, the voltage of the second data line, and the second signal,
wherein the write clock is set to the second power supply voltage in the test mode and the read mode.

17. The input/output circuit of claim 11, wherein the bypass circuit includes an XOR gate having a first input configured to receive the data signal and a second input configured to receive the write enable signal at least through a second inverter and a NOR gate, wherein the XOR gate, the second inverter and the NOR gate are configured to be powered by the first power supply voltage.

18. The input/output circuit of claim 17, wherein the NOR gate has a first input configured to receive a control signal a second input coupled to an output of the second inverter, wherein the control signal is set to the first power supply voltage in the read mode and the write mode, and the control signal is set to a grounding voltage in the test mode.

19. A method for operating an input/output circuit of a memory array, comprising:
directly receiving a data signal and indirectly receiving a write enable signal to generate a bypass data signal, by a bypass circuit;
transmitting the bypass data signal to a first latch, wherein the first latch is coupled to the memory array through a first data line and a second data line, and the first latch comprises:
a first inverter having an input for receiving the bypass data signal;
a first switch coupled between the first data line and the input of the first inverter; and
a second switch coupled between the second data line and an output of the first inverter;
transmitting a logic inverse of the bypass data signal to the first latch;
generating a data output signal based on a voltage presented on the second data line, by a second latch;
providing a first power supply voltage to power the first inverter and the bypass circuit; and
providing a second power supply voltage to power the memory array, the first latch except the first inverter, and the second latch, wherein the second power supply voltage is different from the first power supply voltage.

20. The method of claim 19, wherein further comprising:
activating the first and second switches in a write mode and a test mode of the memory array; and
deactivating the first and second switches in a read mode of the memory array.
